(19) United States
(12) Patent Application Publication
(10) Pub. No.: US 2015/0060505 A1
(43) Pub. Date: Mar. 5, 2015

(54) Case

(71) Applicant: Global Cellular, Inc., Alpharetta, GA (US)

(72) Inventors: Joseph Brown, Alpharetta, GA (US); Nagaraja Rao Vyasateja Jyothigowdanapura, Mysore (IN)

(21) Appl. No.: 14/275,472

(22) Filed: May 12, 2014

Related U.S. Application Data
(60) Provisional application No. 61/870,451, filed on Aug. 27, 2013.

(51) Int. Cl. H05K 5/03; B29D 99/00; B29C 65/00; B29C 65/08

(52) U.S. Cl. CPC H05K 5/03; B29C 65/08; B29D 99/006; B29C 65/00; B29K 2067/003
USPC 224/235; 156/60; 156/73.1

(57) ABSTRACT

Cases for portable electronic devices and methods for making the same. One example of a case includes a tailgate and one or more doors movable between an open and closed orientation to allow the portable electronic device to be laterally slid into an interior of the case between a front and a back of the case. Another example of a case includes a slide for actuating a switch of the portable electronic device in which the slide translates (as opposed to rotates) to actuate the switch. Another example of a case relates to improved manufacturing methods for cases.

### RELATED APPLICATIONS

This patent claims priority to U.S. Provisional Patent Application Ser. No. 61/870,451, filed Sep. 17, 2013 for a “Case,” the entire contents of which are incorporated by this reference.

### RELATED FIELDS

Cases for portable electronic devices and methods for making the same.

### BACKGROUND

There are a wide variety of cases available for use in protecting one's portable electronic devices (e.g. smart-phones or tablet computers) from damage. This patent describes a variety of improved cases, improved case components, and improved manufacturing methods for cases.

### SUMMARY

In one non-limiting example, the case may be a protective case for a portable electronic device, the protective case comprising: (a) a front, the front including a transparent screen protector; (b) a back; (c) a sidewall extending between the front and back, the front, back and sidewall defining an interior configured to receive the portable electronic device by sliding the portable electronic device between the front and the back; (d) a tailgate extending between the front and the back, the tailgate movable between open and closed orientations; and (e) a door extending between the front and the back, the door movable between open and closed orientations; (f) wherein opening the tailgate and the door creates an opening through the sidewall configured to receive the portable electronic device in a sliding fashion.

The protective case may include a door that comprises a first door and a second door, wherein the first door is located at a first corner of the protective case and wherein the second door is located at a second corner of the protective case, wherein the tailgate extends between the first door and the second door when the tailgate and the doors are in the closed orientations.

The protective case may include a tailgate wherein, when the tailgate is in the closed orientation, the tailgate impedes the doors from moving between the open and closed orientations.

The protective case may include first and second doors, wherein the first and second doors define first and second curved sidewall corners of the case.

The protective case may include a tailgate, wherein the tailgate is joined to one of the front or the back at a hinge aligned with an edge of the front or the back.

The protective case may include a tailgate, wherein the tailgate further comprises a latch extending over one of the front or the back when the tailgate is in the closed orientation.

The protective case may include a door, wherein the door is joined to a portion of the sidewall at a hinge aligned with an edge of the portion extending between the front and the back.

The protective case may include a tailgate, wherein the hinge of the tailgate and the hinge of the door are oriented substantially perpendicular to one another.

The protective case may include a transparent screen protector that extends across substantially the entire front of the case.

The protective case may include a transparent screen that further comprises openings extending through the transparent screen protector.

The protective case may include a front that further comprises an anti-slip ring extending about a periphery of the transparent screen protector.

The protective case may include a front that further comprises a stiffening element extending about the periphery of the transparent screen protector.

The protective case may include a front that is joined to the sidewall at a permanent bond.

The protective case may include a front that is joined to the sidewall at an ultrasonic weld.

The protective case may include a front that is substantially planar.

The protective case may include a slide, the slide mounted in an aperture of the sidewall in a sliding fashion such that the slide is configured to translate through a plane aligned with the sidewall, the slide configured to operate a switch of the portable electronic device.

In another non-limiting example, the case may be a protective case for a portable electronic device, the protective case comprising: (a) a front, the front including a transparent screen protector; (b) a back; (c) a sidewall extending between the front and back, the front, back and sidewall defining an interior configured to receive the portable electronic device by sliding the portable electronic device between the front and the back through an opening in the sidewall; and (d) a slide, the slide mounted in an aperture of the sidewall in a sliding fashion such that the slide is configured to translate through a plane aligned with the sidewall, the slide configured to operate a switch of the portable electronic device.

The protective case may include a slide that includes a protrusion extending beyond an interior surface of the sidewall into the interior of the protective case.

The protective case may include a protrusion that includes a channel configured to receive a switch of the portable electronic device in a sliding fashion as portable electronic device is slid into the protective case.

The protective case may include a channel that is open at least at an end of the protrusion facing towards the opening in the sidewall.

The protective case of claim may include a slide that is mounted to the sidewall in a sliding fashion by at least one of a pair of grooves and a pair of rails.

The protective case may include an aperture of the sidewall that includes the pair of rails and wherein the slide includes the pair of grooves.

In another non-limiting example, a method of manufacturing a protective case for a portable electronic device comprises: (a) positioning a first component of the protective case relative to a second component of the protective case, the first component comprising a back and a sidewall of the case, the second component comprising a front of the case including a transparent screen protector, the sidewall defining an opening sized to allow the portable electronic device to be inserted between the back and the front in a sliding fashion through the opening after manufacture; and (b) bonding the first component to the second component.

The method may include bonding the first component to the second component by ultrasonically welding the first component to the second component.

The method may include forming the first component by co-molding a first thermoplastic material and a second thermoplastic material, the first thermoplastic material being a different material from the second thermoplastic material.

The method may include forming the second component by bonding the transparent screen protector to at least one thermoplastic sub-component.

### BRIEF DESCRIPTION OF DRAWINGS

FIG. 1 is a front perspective view of one non-limiting example of a protective case.

FIG. 2 is a rear perspective view of the case of FIG. 1.

FIGS. 3-8 show various components and portions of the case of FIG. 1.

FIG. 9 is a front view of the case of FIG. 1.

FIG. 10 is a rear view of the case of FIG. 1.

FIG. 11 is a left side view of the case of FIG. 1.

FIG. 12 is a right side view of the case of FIG. 1.

FIGS. 13 and 14 are cross-sectional views of the case of FIG. 1.

FIG. 15 is a top view of the case of FIG. 1.

FIG. 16 is a bottom view of the case of FIG. 1.

FIGS. 17 and 18 are cross-sectional views of the case of FIG. 1.

FIGS. 19 and 20 are perspective views of a slide of the case of FIG. 1.

FIGS. 21 and 22 are perspective views of an aperture of a portion of the case of FIG. 1.

FIG. 23 is a perspective view of the case of FIG. 1, shown with a tailgate and doors of the case in one example of an open orientation.

### DETAILED DESCRIPTION OF DRAWINGS

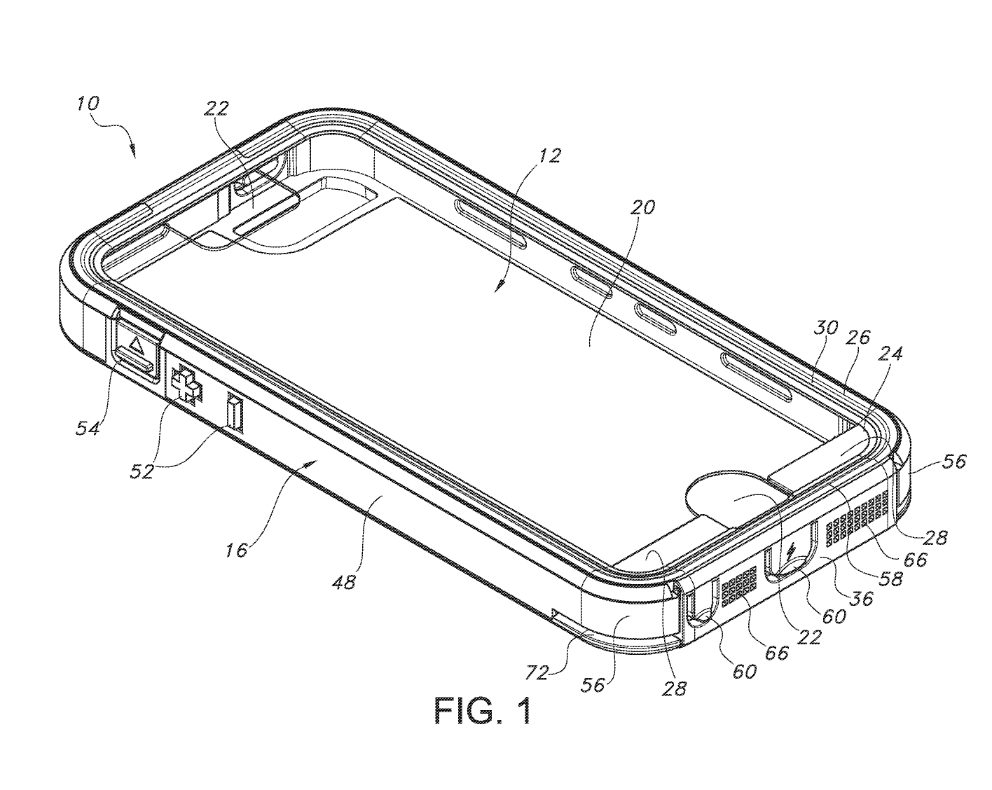

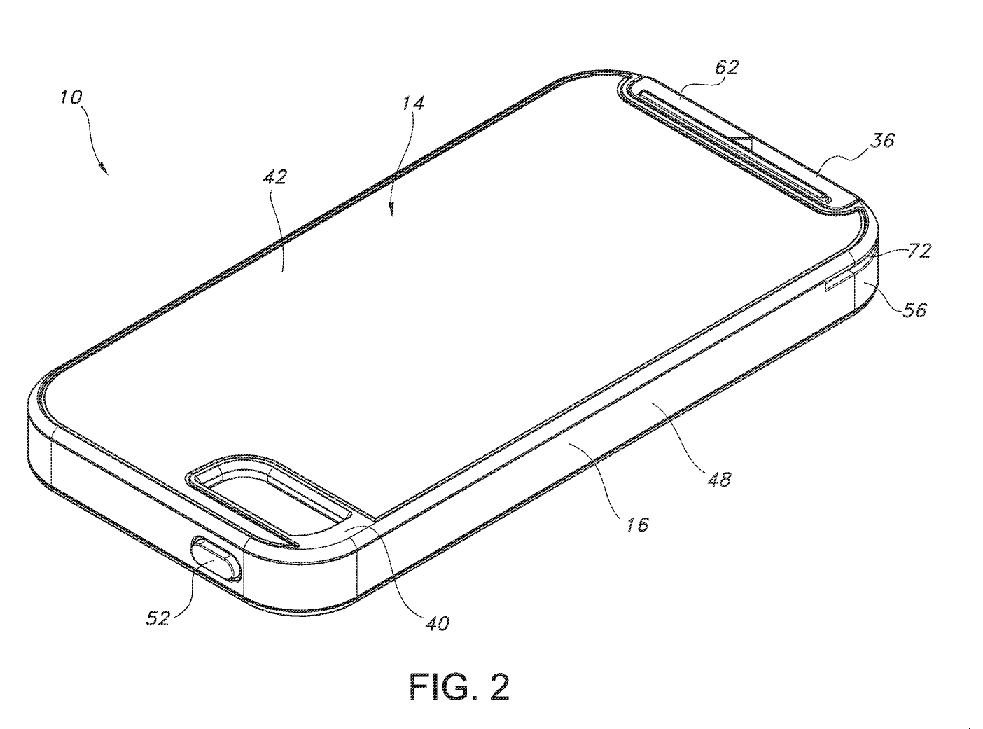

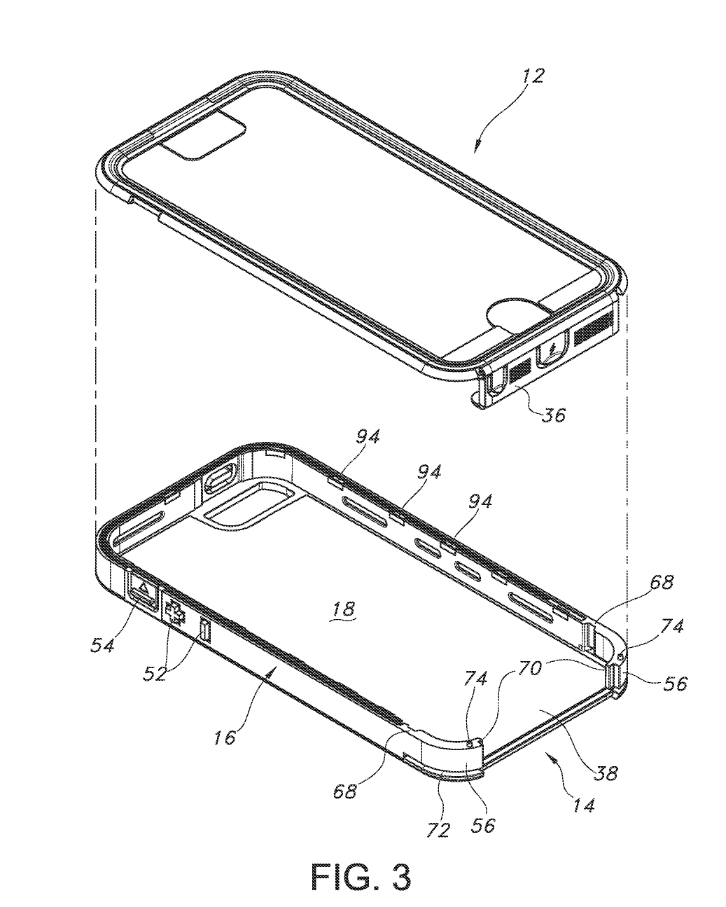

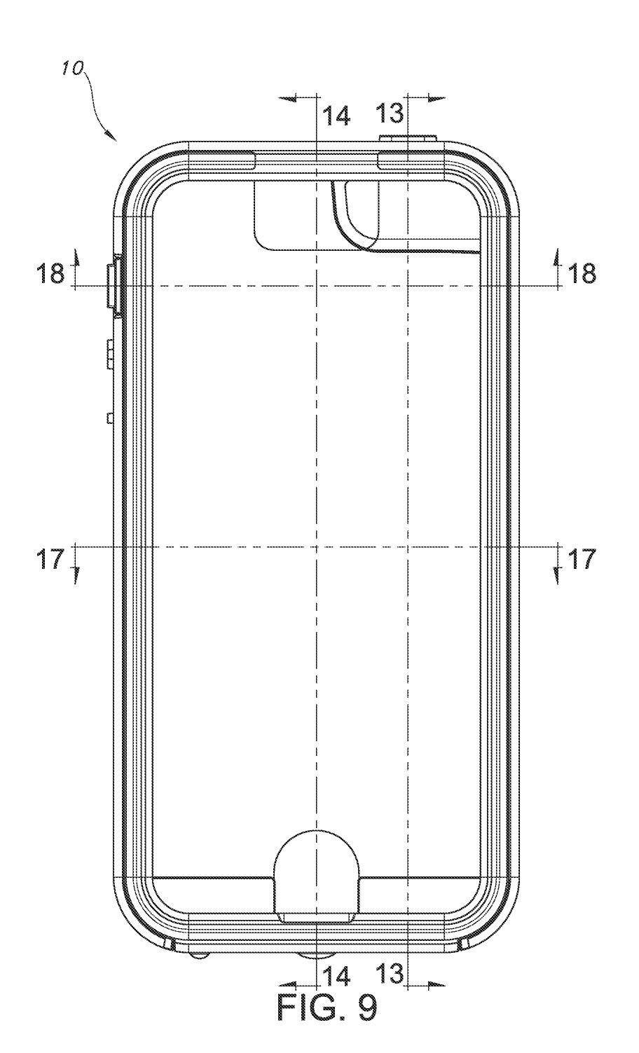

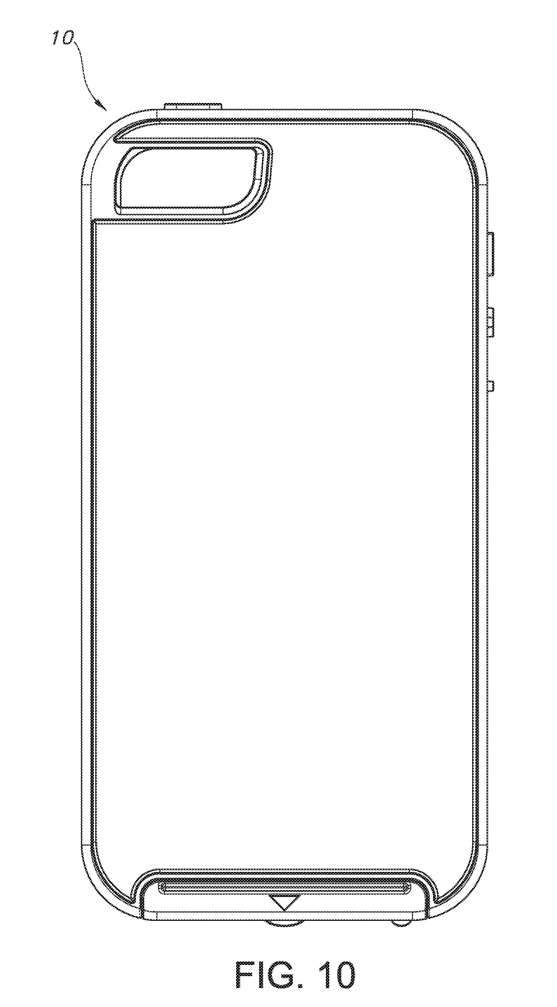

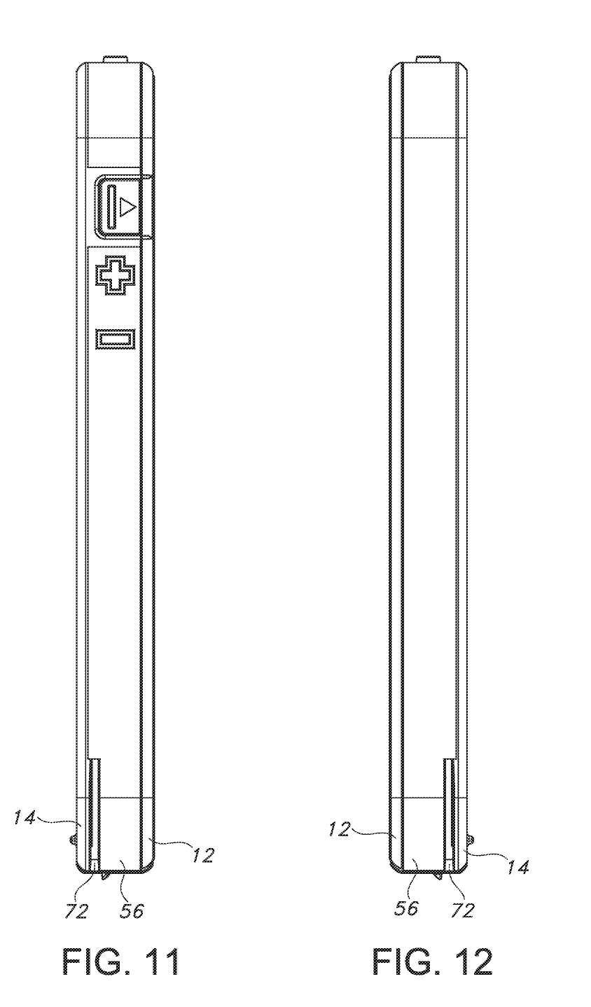

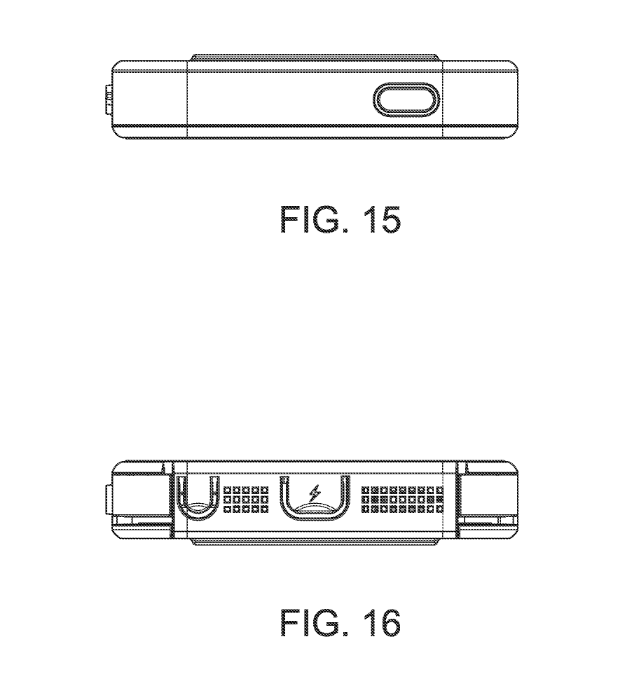

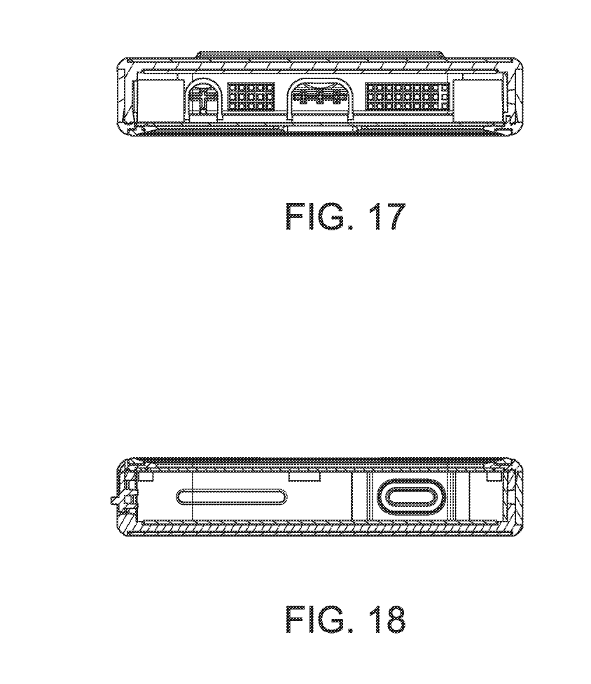

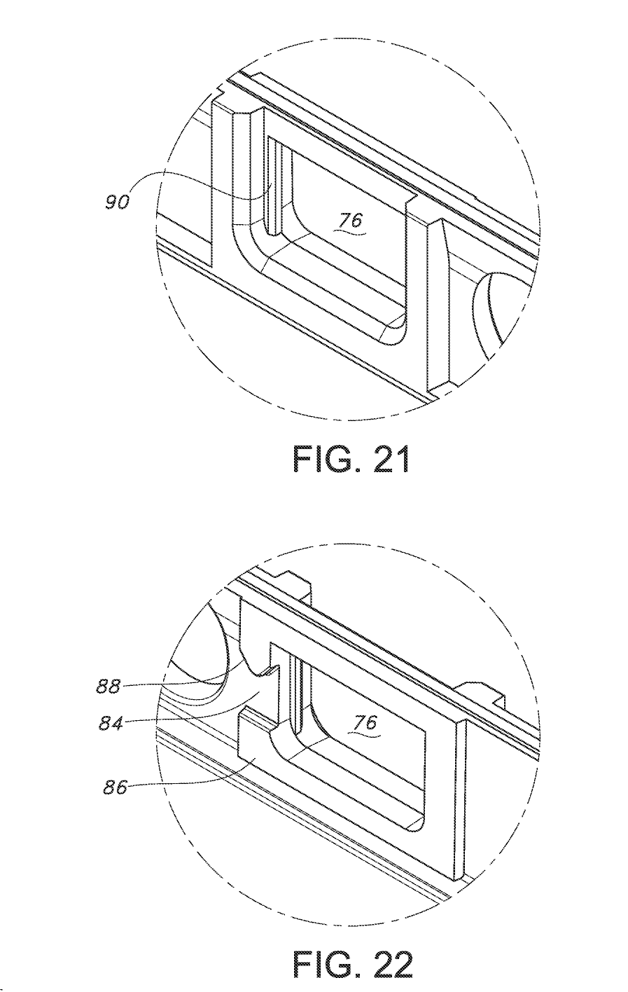

FIGS. 1 through 23 show one non-limiting example of a protective case 10 for a portable electronic device. As shown in FIGS. 1 and 2, the case 10 includes a front 12, a back 14, and a sidewall 16 extending around the perimeter of the case 10 between the front 12 and back 14. The front 12, back 14, and sidewall 16 define an interior 18 (see, e.g. FIG. 3) configured to receive the portable electronic device by sliding the portable electronic device through an opening between the front 12 and back 14, as discussed in further detail below. The case 10 may be sized and otherwise configured for a particular make and model of portable electronic device, or may be sized and otherwise configured for a variety of makes and/or models of portable electronic devices.

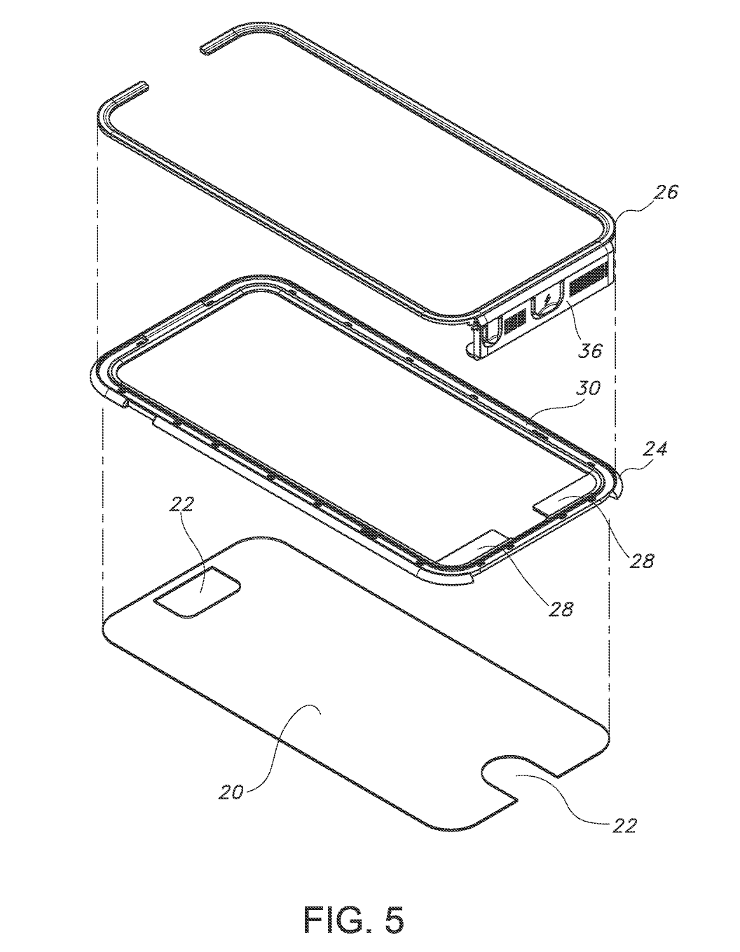

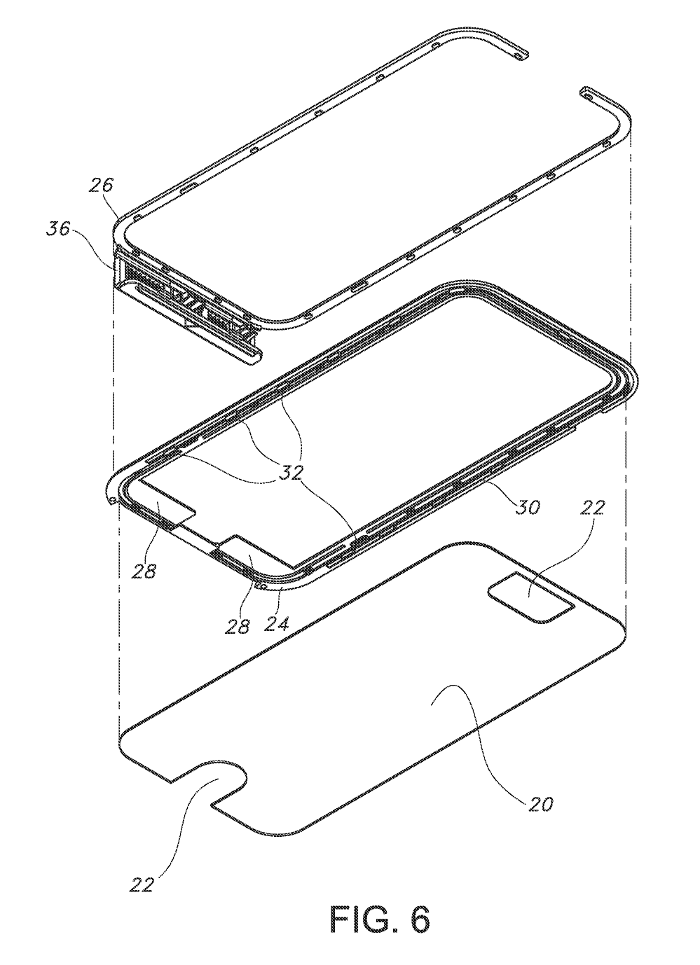

As shown in FIGS. 5 and 6, the front 12 of the case 10 includes a transparent screen protector 20. In this example, the transparent screen protector 20 is made out of PET film that is die cut to the specific shape of the case. The PET film may have a 2H hardness and an inner textured screen to prevent or reduce water marks. In other examples, the screen protector may be a clear polycarbonate, poly-urethane film, RPET film, glass, or armor glass. In the embodiment shown, the screen protector 20 includes openings 22 extending through the screen protector 20, located over particular components of the portable electronic device, although in other embodiments the transparent screen protector 20 does not include such openings or includes an additional film or other material covering the openings.

The screen protector 20 extends across substantially the entire front 12 of the case 10. For instance, the screen protector 20 extends at least partially over the sidewall 16 on left, right, upper, and lower sides of the case 10. In other embodiments, the screen protector 20 may extend to, although not necessarily over, the sidewall 16. In still other embodiments, the screen protector does not extend to the sidewall 16.

As shown in FIGS. 5 and 6, the front 12 of the case 10 also includes a stiffening element 24 and an anti-slip ring 26 on top of the screen protector 20. In this embodiment, the anti-slip ring 26 and the stiffening element 24 are opaque or semi-opaque. FIGS. 5 and 6 also show a tailgate 36 that is part of the sidewall 16 of the case 10 and is discussed further below.

In the embodiment shown, the stiffening element 24 is polycarbonate and is configured to increase the stiffness of the front 12 of the case 10. The stiffening element 24 includes two planar panels 28 on either side of one of the openings 22 and a ring 30 extending about the perimeter of the front 12. In the embodiment shown, the ring 30 is less than 2.5 mm thick (and in other embodiments may be between 3 mm and 1 mm thick). As shown in FIG. 6, the stiffening element 24 includes a recess for receiving the screen protector 20, and also includes protrusions 32 extending from a back side of the stiffening element 28, the purpose of which will be described in further detail below.

In the embodiment shown, the anti-slip ring 26 is a thermoplastic elastomer (although in other embodiments it may be a silicone) and is configured to sit in a groove formed in a front side of the stiffening element 24 such that only a very thin portion of the anti-slip ring 26 extends above the top of the stiffening element 24 (e.g. 0.5 mm or less). In the embodiment shown, the combined stiffening element 24 and anti-slip ring 26 extend less than 3.2 mm above the front surface of the transparent screen protector. In the embodiment shown, the front 12 of the case 10 is substantially planar.

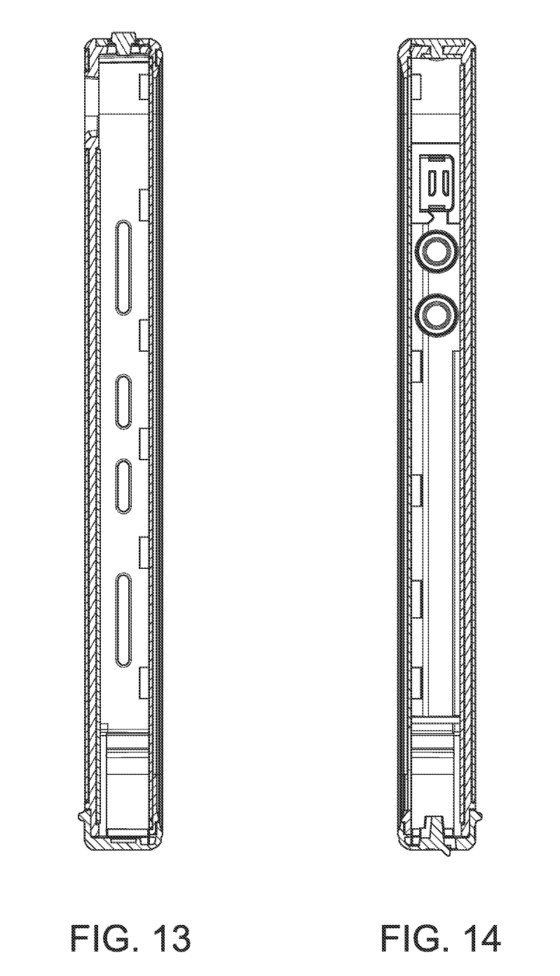

As shown in FIGS. 13, 14, 17, and 18, a ramped surface 34 extends gradually upward from the exposed surface of the screen protector 20 (i.e. the portion of the screen protector 20 not covered by the stiffening element 24 and anti-slip ring 26). In the particular embodiment shown, the ramped surface 34 is slightly concave (although in other embodiments it may be straight) in cross-section and extends away from the screen protector 20 at an obtuse angle (e.g. in the range of 135 degrees to 170 degrees). In some non-limiting embodiments, the angle of the ramped surface 34 facilitates user interaction with the device's touchscreen.

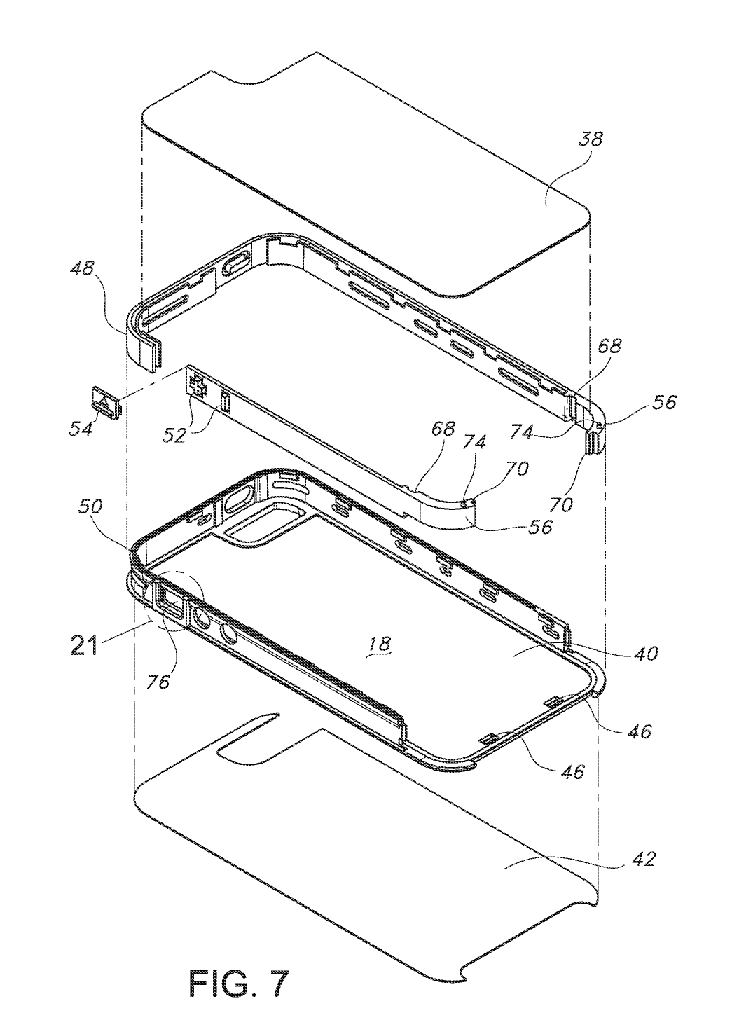

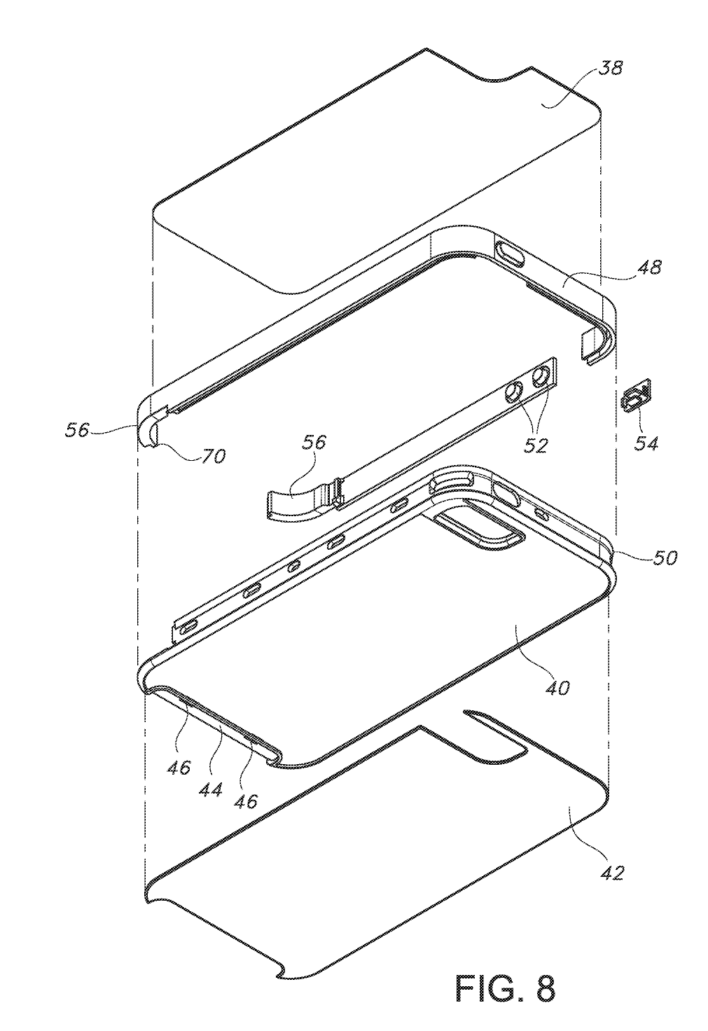

In the embodiment shown in the figures, the back 14 of the case 10 includes multiple layers (see, e.g., FIGS. 7 and 8), including an inner liner 38, a back planar member 40, and a back plate 42. In this example, the inner liner 38 is a silicone padding layer, the back planar member 40 is an opaque polycarbonate, and the back plate 42 is a decorative layer (e.g. a metal, wood, faux-wood, or other material with or without printed graphics or engraved designs) adhered or otherwise affixed to the back planar member 40, or may be a thermoplastic material (e.g. a thermoplastic elastomer) co-molded with the back planar member. In other embodiments, the back 14 of the case 10 may be configured in other ways and have additional or less layers.

As shown in FIGS. 7 and 8 the back planar member 40 and the back plate 42 are notched to provide clearance for the tailgate 36 discussed in greater detail below. As also shown in FIGS. 7 and 8, the planar surface of back planar member 40 includes a recess 44 for receiving a portion of the tailgate 36, and includes connectors (in this instance, apertures 46) for securing portions of the tailgate 36. The inner liner 38, back planar member 40, and back plate 42 also include apertures/notches to provide a camera opening for the electronic device.

FIGS. 7 and 8 also show the sidewall 16 of the case 10 (except for the tailgate 36, which is formed in this example with the anti-slip ring 26, as shown in FIGS. 5 and 6). In this particular example, the sidewall 16 includes a thermoplastic elastomer portion 48 and a polycarbonate portion 50, although other configurations are also possible. The sidewall 16 includes buttons 52 for actuating some of the controls of the electronic device and also includes a slide 54 for actuating other controls (in this example, specifically the switch for silencing the electronic device), which is discussed in further detail below.

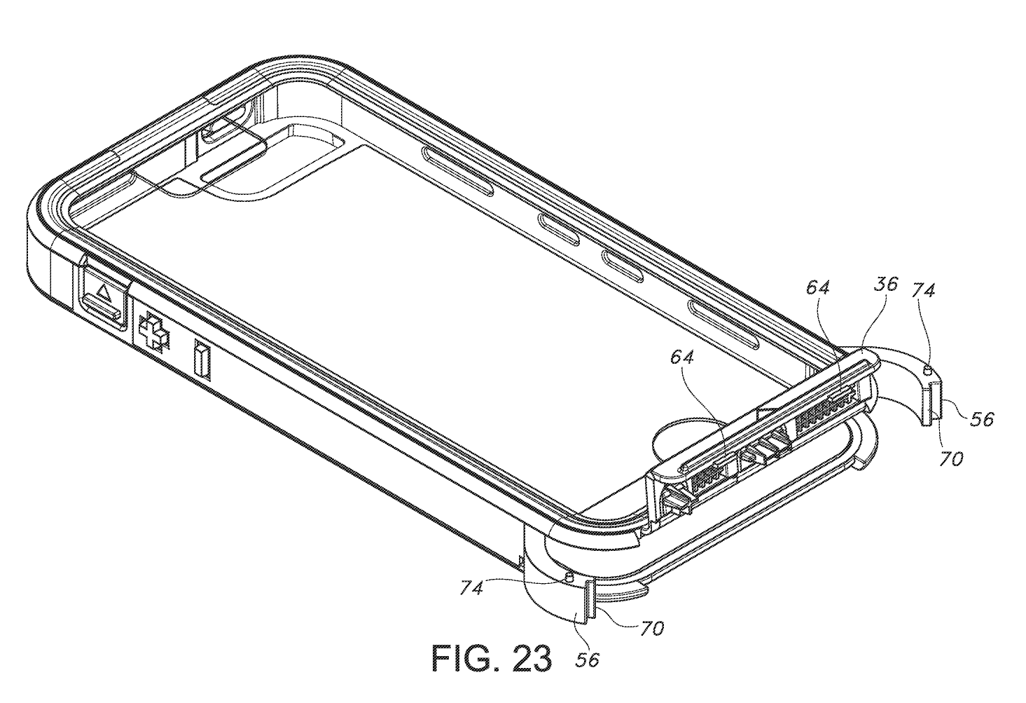

The case 10 shown in the figures allows the portable electronic device to be inserted into its interior 18 through an opening in the sidewall 16 created by opening a tailgate 36 and doors 56 of the sidewall 16. FIG. 1 shows the tailgate 36 and doors 56 in a closed orientation. FIG. 23 shows the tailgate 36 and the doors 56 in an open orientation. When the tailgate 36 and the doors 46 are in the open orientation of FIG. 23, the portable electronic device may be slid laterally into the interior 18 of the case 10, and the tailgate 36 and doors 46 may be subsequently re-closed. In some embodiments, the portable electronic device slides along an axis that is parallel to the substantially planar front 12 and back 14 of the case. In some embodiments, the portable electronic device laterally slides into the interior of the case through an opening of the sidewall 16. In the embodiment shown in the figures, the portable electronic device slides through an opening in the bottom of the case. In other embodiments, the portable electronic device slides through an opening the top, left, or right side of the case.

The tailgate 36 shown in the figures extends between the front 12 and back 14 of the case when it is in the closed configuration. The tailgate 36 is joined to the front 12 of the case 10 at a hinge 58. In the particular embodiment shown, the hinge 58 is a living hinge (i.e. it is formed as an integral portion of the tailgate 36 and anti-slip ring 26 and is resilient such that the tailgate 36 can be rotated about the long axis of the hinge 58). In the embodiment shown, the rotational axis of the hinge 58 is aligned with (or coincides with) an edge of the front 12. In the embodiment shown, the rotation axis of the hinge 58 is parallel with and slightly offset from the portion of the anti-slip ring 26 closest to the tailgate 36.

The tailgate 36 also includes plugs 60 that may be rotated relative to other portions of the tailgate (for accessing a charging port and headphone jack of the electronic device). The tailgate 36 also includes speaker grills 66. The tailgate 36 also includes a latch portion 62 that fits into the recess 44 of the back planar member 40 when the tailgate 36 is in the closed orientation. Connectors on the latch portion (in this instance, protrusions 64, see FIG. 23) fit into apertures 46 of the back planar member 44 to help retain the tailgate 36 in the closed orientation. In the particular example show, the protrusions 64 extend outwardly and parallel to the latch portion. In other embodiments, the protrusions may extend outwardly and perpendicular to the latch portion. In some embodiments, the protrusions may have a triangular or other cross sectional shape that increases in width as the protrusions extend away from the latch portion to provide a firm engagement with the apertures or other structure of the case to help retain the tailgate in a closed orientation.

The doors 56 shown in the figures extend between the front 12 and back 14 when the doors 56 are in closed orientations. The doors 56 in the example shown in the figures form two corners of the sidewall 16 of the case, on either side of the tailgate 36. As shown in FIGS. 1 and 23, the doors 56 define curved portions of the sidewall 16. As shown in FIG. 3, for example, each door 56 is associated with a hinge 68 (here, also a living hinge created by an area of reduced thickness of the thermoplastic elastomer portion of the sidewall 16). Hinges 68 are generally perpendicular to the front 12 and back 14 of the case 10. Hinges 68 are aligned with edges of the sidewall 16 that join to the hinges 68.

In the example shown in the figures, the axes of rotation of hinges 68 are substantially perpendicular to the hinge 58 of tailgate 36. In the example shown in the figures, the doors 56 rotate outwardly from the sidewall 16 of the case 10 whereas the tailgate 36 rotates upwardly away from the back 14 and towards the front 12.

When the tailgate 36 and doors 56 are in the closed orientations, the tailgate 36 inhibits or impedes the doors 56 from opening. As shown in FIGS. 7, 8 and 23, the doors 56 include vertically oriented lips 70 that are captured by the tailgate 36 when the tailgate 36 and doors 56 are in closed orientations, such that the doors 56 cannot be opened until the tailgate 36 is rotated to an open orientation, such as shown in FIG. 23.

As shown in FIGS. 1, 11, and 12, the doors 56 define elongated gaps 72 between the doors 56 and back 14 of the case 10, which, in the example shown, offset the door further away from the back 14 of the case 10 than the front 12 of the case 10. In other words, in the example shown, the gaps 72 between the doors 56 and the back 14 of the case are wider than gaps (to the extent there is one) between the doors 56 and the front 12 of the case. Although not shown in the figures, in some embodiments, the doors 56 may include small support members extending through the gaps 72 to the back 14 to further strengthen the case 10 against certain loads or forces. As shown in, for example, FIG. 23, the doors 56 may also include protrusions 74 on upper surfaces of the doors 56 for engaging recesses in an underside surface of the front 12 of the case to facilitate retaining doors 56 in the closed orientation. In still other examples, gaps are not necessary or are minimal in size, and supports/protrusions on the doors are not necessary or are smaller in size. In still other examples, the doors are not necessarily uniform in size. In other words, one door may be larger than the other door. In some examples, one of the doors may take the place of the tailgate (e.g. the door extends all the way or almost all the way across the bottom of the case).

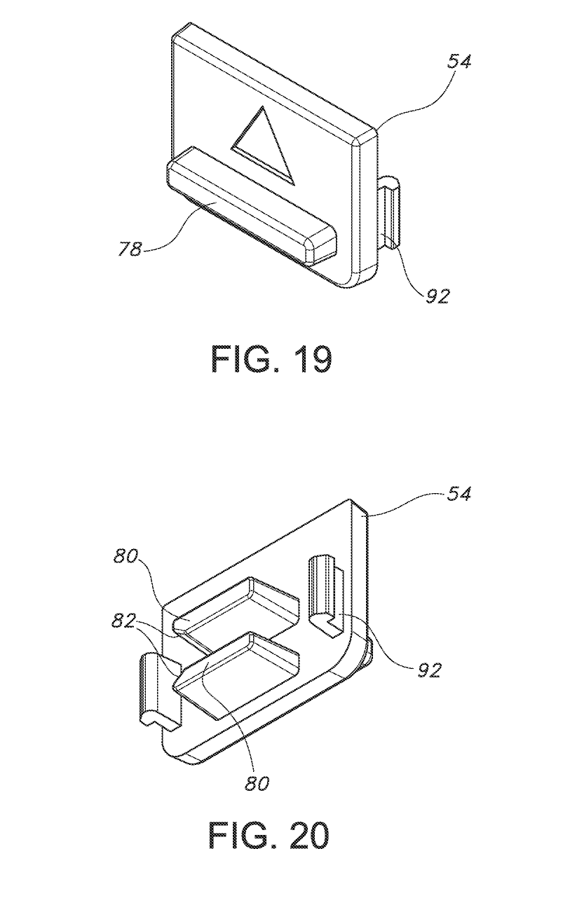

FIGS. 19 through 22 show the afore-mentioned slide 54 and portions of sidewall 16 that interact with the slide 54. An outer surface of the slide 54 (shown in FIG. 19) includes a protrusion 78 for helping a user actuate slide 54. An inner surface of slide 54 (shown in FIG. 20) includes structure for interacting with a switch (such as a toggle switch) of the portable electronic device. In the specific example shown, the structure for interacting with the switch includes two protrusions 80 extending from the back surface of slide 54 such that, when mounted in the sidewall 16, the protrusions 80 extend beyond the sidewall 16 into the interior 18 of case 10 such that the protrusions 80 can contact the switch of the electronic device during use. Protrusions 80 define a channel between them for receiving the switch of the electronic device. Ramped surfaces 82 on the protrusions 80 (which may be straight or curved) are on the sides of the protrusions 80 facing towards the insertion opening of case 10, such that the ramped surfaces 82 can interact with the switch of the electronic device as it is slid between the front 12 and back 14 of the case into its interior 18, such that the slide 54 will align with the switch of the electronic device and not substantially impede insertion of the electronic device into the case 10. As shown in FIG. 22, a channel 84 extends through a raised portion 86 of the interior of the sidewall 16 to provide clearance for the switch of the electronic device as it is slid into the case 10. In the particular example shown, channel 84 also includes a ramped surface 88, which will facilitate aligning the switch of the electronic device such that it does not significantly impede insertion into the case 10.

Slide 54 mounts in an aperture 76 of the sidewall 16 in a sliding fashion such that the slide is configured to translate through a plane aligned with the sidewall. In the particular example shown, the slide 54, when mounted in aperture 76, can translate through a portion of the aperture 76, but cannot rotate or pivot in or relative to the aperture 76. In the particular example shown in the figures, the translational movement of the slide 54 in the aperture 76 is controlled by a pair of rails 90 and a pair of grooves 92. In the particular example shown, the rails 90 extend into aperture 76, and are aligned with an axis extending between the front 12 and back 14 of the case 10. In the particular example shown the grooves 92 are formed by protrusions extending from the rear surface of slider 54, such grooves also aligned with an axis extending between the front 12 and back 14 of the case 10 when the slider 54 is mounted in the aperture 76. As shown in FIG. 20, the protrusions forming the grooves 92 are shorter than the protrusions 80 for interacting with the electronic device's switch.

While not shown in the figures, in some examples, the case may include an ejector mechanism to facilitate removal of the electronic device from the case. In one example, the case may include a pusher or slider that, when depressed or slid, moves the electronic device towards the opening in the case, to facilitate its removal.

The case 10 shown in the figures may be formed from a variety of materials. Some (or all) of the materials forming the case may be molded. Portions of the front 12, back 14, and sidewall 16 of the case may be formed by one or more co-molding, over-molding, or other molding processes. In the specific example shown in the figures, the front 12 of the case 10 is formed by co-molding or over molding a poly-carbonate thermo-plastic stiffening element 24 and a thermo-plastic elastomer anti-slip ring 26 (the tailgate 36 also being integrally formed with the thermo-plastic elastomer anti-slip ring 26). The transparent screen protector 20 may be joined to one or both of the other components shown in FIGS. 5 and 6 by an adhesive, ultrasonic welding, or other methods. In other embodiments, the transparent screen protector 20 may be snap fit into the front of the case (and, in some instances, may be removable/replaceable). In the specific example shown in the figures, the back 14 and sidewall 16 of the case is formed by co-molding or over molding a poly-carbonate thermo-plastic portion (including a portion 50 of sidewall 16 and the back planar member 42) and a thermo-plastic elastomer portion 48 of the sidewall 16. The inner liner 38 may be joined to the back planar member 42 by adhesive or other mechanisms. The back plate 42 may be jointed to the back planar member 42 by adhesive, ultra-sonic welding, co-molding or over-molding, or by other mechanisms.

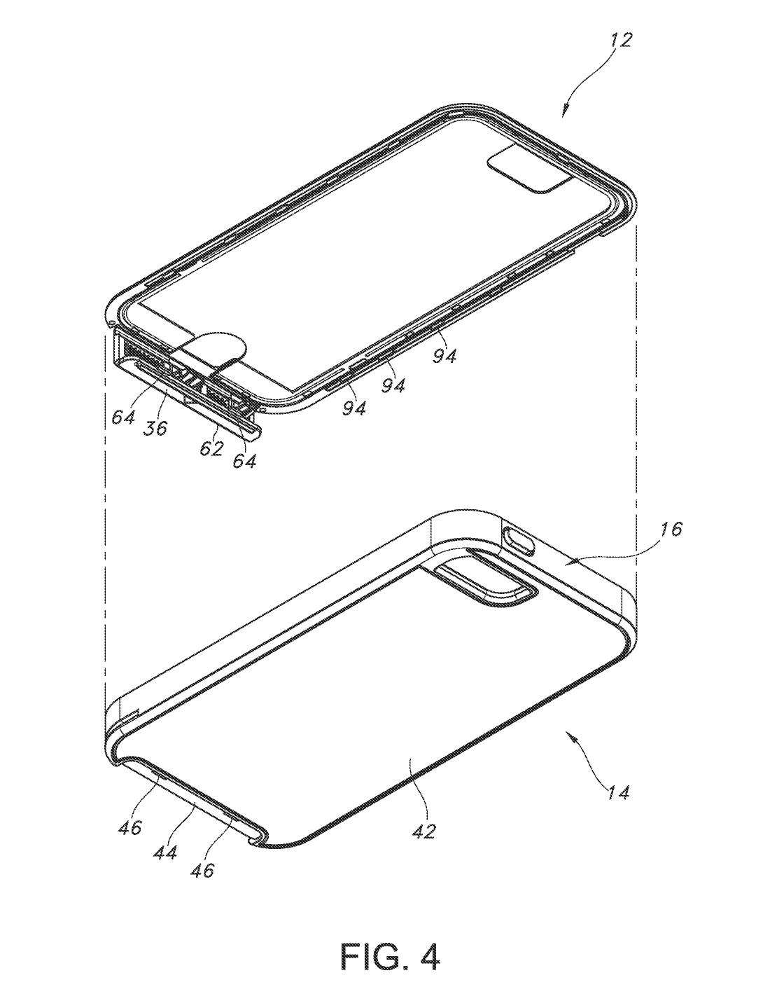

In the particular embodiment shown, such as illustrated in FIGS. 3 and 4, once the front 12 construct and the back 14 and sidewall 16 construct are formed, those two constructs may be joined together to complete manufacture of the case 10. In some instances, those two constructs may be joined permanently to one another, such as by ultrasonically welding the two constructs together. In the particular example shown in the figures, protrusions and recesses 94 on those constructs may facilitate alignment of the two constructs relative to one another during manufacture.

Those of ordinary skill in the art will recognize that additions, deletions, substitutions, and other changes or modifications may be made to the case 10 shown in the figures and described above without departing from the scope or spirit of the present inventions reflected by this patent, which are specified by the claims of this patent.

1. A protective case for a portable electronic device, the protective case comprising:
(a) a front, the front including a transparent screen protector;
(b) a back;
(c) a sidewall extending between the front and back, the front, back and sidewall defining an interior configured to receive the portable electronic device by sliding the portable electronic device between the front and the back;
(d) a tailgate extending between the front and the back, the tailgate movable between open and closed orientations; and
(e) a door extending between the front and the back, the door movable between open and closed orientations;
(f) wherein opening the tailgate and the door creates an opening through the sidewall configured to receive the portable electronic device in a sliding fashion.

2. The protective case of claim 1, wherein the door comprises a first door and a second door, wherein the first door is located at a first corner of the protective case and wherein the second door is located at a second corner of the protective case, wherein the tailgate extends between the first door and the second door when the tailgate and the doors are in the closed orientations.

3. The protective case of claim 2, wherein, when the tailgate is in the closed orientation, the tailgate impedes the doors from moving between the open and closed orientations.

4. The protective case of claim 2, wherein the first and second doors define first and second curved sidewall corners of the case.

5. The protective case of claim 1, wherein the tailgate is joined to one of the front or the back at a hinge aligned with an edge of the front or the back.

6. The protective case of claim 5, wherein the tailgate further comprises a latch extending over one of the front or the back when the tailgate is in the closed orientation.

7. The protective case of claim 5, wherein the door is joined to a portion of the sidewall at a hinge aligned with an edge of the portion extending between the front and the back.

8. The protective case of claim 7, wherein the hinge of the tailgate and the hinge of the door are oriented substantially perpendicular to one another.

9. The protective case of claim 1, wherein the transparent screen protector extends across substantially the entire front of the case.

10. The protective case of claim 9, wherein the transparent screen further comprises openings extending through the transparent screen protector.

11. The protective case of claim 9, wherein the front further comprises an anti-slip ring extending about a periphery of the transparent screen protector.

12. The protective case of claim 11, wherein the front further comprises a stiffening element extending about the periphery of the transparent screen protector.

13. The protective case of claim 1, wherein the front is joined to the sidewall at a permanent bond.

14. The protective case of claim 13, wherein the front is joined to the sidewall at an ultrasonic weld.

12. The protective case of claim 11, wherein the front is substantially planar.

13. The protective case of claim 1, further comprising a slide, the slide mounted in an aperture of the sidewall in a sliding fashion such that the slide is configured to translate through a plane aligned with the sidewall, the slide configured to operate a switch of the portable electronic device.

14. A protective case for a portable electronic device, the protective case comprising:
(a) a front, the front including a transparent screen protector;
(b) a back;
(c) a sidewall extending between the front and back, the front, back and sidewall defining an interior configured to receive the portable electronic device by sliding the portable electronic device between the front and the back through an opening in the sidewall; and
(d) a slide, the slide mounted in an aperture of the sidewall in a sliding fashion such that the slide is configured to translate through a plane aligned with the sidewall, the slide configured to operate a switch of the portable electronic device.

15. The protective case of claim 14, wherein the slide includes a protrusion extending beyond an interior surface of the sidewall into the interior of the protective case.

16. The protective case of claim 15, wherein the protrusion includes a channel configured to receive a switch of the portable electronic device in a sliding fashion as portable electronic device is slid into the protective case.

17. The protective case of claim 16, wherein the channel is open at least at an end of the protrusion facing towards the opening in the sidewall.

18. The protective case of claim 14, wherein the slide is mounted to the sidewall in a sliding fashion by at least one of a pair of grooves and a pair of rails.

19. The protective case of claim 18, wherein the aperture of the sidewall includes the pair of rails and wherein the slide includes the pair of grooves.

20. A method of manufacturing a protective case for a portable electronic device, the method comprising:
(a) positioning a first component of the protective case relative to a second component of the protective case, the first component comprising a back and a sidewall of the case, the second component comprising a front of the case including a transparent screen protector, the sidewall defining an opening sized to allow the portable electronic device to be inserted between the back and the front in a sliding fashion through the opening after manufacture;
(b) bonding the first component to the second component.

21. The method of claim 20, wherein bonding the first component to the second component comprise ultrasonically welding the first component to the second component.

22. The method of claim 21, further comprising forming the first component by co-molding a first thermoplastic material and a second thermoplastic material, the first thermoplastic material being a different material from the second thermoplastic material.

23. The method of claim 22, further comprising forming the second component by bonding the transparent screen protector to at least one thermoplastic sub-component.
